(19) United States
(12) Patent Application Publication
(10) Pub. No.: US 2024/0072732 A1
(43) Pub. Date: Feb. 29, 2024

(54) TRANSISTOR DIE INCLUDING MATCHING CIRCUIT

(71) Applicant: Wolfspeed, Inc., Durham, NC (US)

(72) Inventors: Donald Farrell, Raleigh, NC (US); Dan Namishia, Wake Forest, NC (US); Kyle Bothe, Cary, NC (US); Brad Millon, Durham, NC (US)

(21) Appl. No.: 17/900,652

(22) Filed: Aug. 31, 2022

(51) Int. Cl. H03F 1/02; H01L 23/66; H03F 1/56; H03F 3/195

(52) U.S. Cl. CPC H03F 1/0288; H01L 23/66; H03F 1/565; H03F 3/195; H01L 2223/6611; H01L 2223/6655; H03F 2200/451

(57) ABSTRACT

A transistor die includes a transistor including a control terminal, an output terminal, and a first partial matching circuit. The first partial matching circuit is connected to at least one of the control terminal of the transistor and the output terminal of the transistor, and is configured to tune an input impedance of the transistor die. A packaged device is also provided.

### FIELD

The present disclosure relates to a transistor die, in particular a transistor die including a matching circuit, and a related package.

### BACKGROUND

The present disclosure relates to transistor dies and packaged transistor dies, and in particular to transistor dies that include a matching circuit(s) on the transistor die.

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H-SiC at room temperature) and the Group III nitrides (e.g., 3.36 eV for GaN at room temperature). These materials may have higher electric field breakdown strengths and higher electron saturation velocities than GaAs and Si.

A device of particular interest for high power and/or high frequency applications is the High Electron Mobility Transistor (HEMT), which is also known as a modulation doped field effect transistor (MODFET). In a HEMT device, a two-dimensional electron gas (2DEG) may be formed at the heterojunction of two semiconductor materials with different bandgap energies, where the smaller bandgap material has a higher electron affinity than the wider bandgap material. The 2DEG is an accumulation layer in the undoped smaller bandgap material and can contain a relatively high sheet electron concentration, for example, in excess of 10¹³ carriers/cm². Additionally, electrons that originate in the wider bandgap semiconductor may transfer to the 2DEG, allowing a relatively high electron mobility due to reduced ionized impurity scattering. This combination of relatively high carrier concentration and carrier mobility can give the HEMT a relatively large transconductance and may provide a performance advantage over metal-semiconductor field effect transistors (MESFETS) for high-frequency applications.

HEMTs fabricated in the gallium nitride/aluminum gallium nitride (GaN/AlGaN) material system can generate large amounts of RF power due to a combination of material characteristics, such as relatively high breakdown fields, relatively wide bandgaps, relatively large conduction band offset, and/or relatively high saturated electron drift velocity. A major portion of the electrons in the 2DEG may be attributed to polarization in the AlGaN.

A GaN-based HEMT can be formed on a silicon carbide substrate. A GaN channel layer can be on the substrate, and an AlGaN barrier layer can be on the channel layer. A 2DEG can arise in the channel layer adjacent the barrier layer. A source contact and a drain contact can be formed on the channel layer. The conductivity of the 2DEG can be modulated by applying a voltage to a gate that can be formed on the barrier layer between the source contact and the drain contact.

Packaged transistors have been used that include a transistor (e.g., a HEMT) in a metal-based package along with matching components of an input matching circuit and/or an output matching circuit between the package leads and transistor gate and drain pads. The matching components of the input matching circuit and/or an output matching circuit of the package typically are used to match an impedance (e.g., 50 ohms) for a particular frequency (e.g., 3.1 GHz) or a particular frequency range (e.g., 3.1-3.5 GHz).

FIGS. 1A-1C are functional block diagrams of a conventional packaged transistor. As shown in FIG. 1A, package 10 can include a transistor 16 (which may be a HEMT, for example) and an input matching circuit 12 connecting a RF signal input lead 14 to a control electrode of the transistor 16 (e.g., a gate G of a HEMT). A RF signal output lead 18 is connected to an output electrode of transistor 16 (e.g., the drain D of a HEMT). The RF signal input lead 14 and the RF signal output lead 18 extend outside the package 10. The source S of the transistor 16 may be grounded. An output matching circuit 20 is connected to the RF signal output lead 18.

As shown in FIG. 1B, package 10 can include transistor 16 and an output matching circuit 12 connecting a RF signal output lead 18 to an output electrode of transistor 16 (e.g., the drain D of a HEMT). A RF signal input lead 14 is connected to a control electrode of the transistor 16 (e.g., a gate of a HEMT). The RF signal input lead 14 and the RF signal output lead 18 extend outside the package 10. The source S of the transistor 16 may be grounded. An input matching circuit 12 is connected to the RF signal input lead 14.

As shown in FIG. 1C, package 10 can include transistor 16, an input matching circuit 12, and an output matching circuit 20. Input matching circuit 12 connects RF signal input lead 14 to a control electrode of the transistor 16 (e.g., a gate G of a HEMT); and output matching circuit 20 connects RF signal output lead 18 to an output electrode of transistor 16 (e.g., the drain D of a HEMT). The source S of the transistor 16 may be grounded.

A bias/RF diplexer (not shown) may be connected to output matching circuit 20 or transistor 16 to connect the transistor 16 output to an RF output. A DC power supply (not shown) also may be connected to the transistor output lead 18. The components of package 10 (transistor 16 and input matching circuit 12/output matching circuit 20) can be mounted on a printed circuit board (not shown).

### SUMMARY

A transistor die according to some embodiments includes a transistor including a control terminal and an output terminal. The transistor die further includes a first partial matching circuit connected to at least one of the control terminal of the transistor and the output terminal of the transistor. The first partial matching circuit is configured to tune an input impedance of the transistor die.

The transistor device may further include the control terminal and the output terminal of the transistor coupled to a package including the transistor die. The package includes a second partial matching circuit for the transistor die.

The second partial matching circuit for the transistor die may be tunable for the transistor die to operate at a plurality of frequencies.

To tune the input impedance of the transistor die may include to increase the input impedance of the transistor die.

The first partial matching circuit may include an input partial matching circuit connected to the control terminal of the transistor.

The first partial matching circuit may include an output partial matching circuit connected to the output terminal of the transistor.

In some embodiments, the first partial matching circuit can include an input partial matching circuit connected to the control terminal of the transistor and/or an output partial matching circuit connected to the output terminal of the transistor.

The first partial matching circuit may include a resonator circuit.

In some embodiments, the resonator circuit can include a series resonator circuit including an inductive element and a shunt capacitor connected in series to a ground terminal.

The resonator circuit may include a shunt inductive element.

The resonator circuit may include a series capacitor.

The resonator circuit may be selected to increase an input impedance of the transistor die.

In some embodiments, the first partial matching circuit may terminate a second harmonic frequency of a signal at a fundamental operating frequency of the transistor die.

A power transistor die according to some embodiments includes a transistor including a control terminal and an output terminal and is configured to operate a fundamental operating frequency. The power transistor die further includes a first matching circuit connected to at least one of the control terminal of the transistor and the output terminal of the transistor. The first matching circuit is configured to tune an input impedance of the transistor die for signals at a harmonic frequency of the fundamental operating frequency. The power transistor die further includes the control terminal and the output terminal of the transistor coupled to a package comprising the transistor die. The package includes a second matching circuit for the transistor die that is tunable for the transistor die to operate at a plurality of frequencies.

The first matching circuit may include an input matching circuit connected to the control terminal of the transistor.

In some embodiments, to tune the input impedance of the transistor die includes to increase the input impedance of the transistor die.

The first matching circuit may include an output matching circuit connected to the output terminal of the transistor.

The first matching circuit may include an input matching circuit connected to the control terminal of the transistor and/or an output matching circuit connected to the output terminal of the transistor.

The first matching circuit may include a resonator circuit.

In some embodiments, the resonator circuit includes a series resonator circuit including an inductive element and a shunt capacitor connected in series to a ground terminal.

The resonator circuit may include a shunt inductive element.

The resonator circuit may include a series capacitor.

In some embodiments, the resonator circuit is selected to increase an input impedance of the power transistor die.

A packaged device according to some embodiments includes a transistor die. The transistor die includes a transistor including a control terminal and an output terminal. The transistor die further includes a first partial matching circuit connected to at least one of the control terminal of the transistor and the output terminal of the transistor. The first partial matching circuit is configured to tune an input impedance of the transistor die. The packaged device further includes a package that houses the transistor die and the first partial matching circuit.

In some embodiments, the control terminal and the output terminal of the transistor are coupled to the package including the transistor die. The package further includes a second partial matching circuit for the transistor die.

The second partial matching circuit for the transistor die may be tunable for the transistor die to operate at a plurality of frequencies.

The input impedance of the transistor die may include to increase the input impedance of the transistor die.

A packaged device according to other embodiments includes a power transistor die including a transistor, the transistor including a control terminal and an output terminal and is configured to operate a fundamental operating frequency. The power transistor die further includes a first matching circuit connected to at least one of the control terminal of the transistor and the output terminal of the transistor. The first matching circuit is configured to tune an input impedance of the transistor die for signals at a harmonic frequency of the fundamental operating frequency. The control terminal and the output terminal of the transistor are coupled to a package including the transistor die. The package further includes second matching circuit for the transistor die that is tunable for the transistor die to operate at a plurality of frequencies. The package houses the power transistor die, the first matching circuit, and the second matching circuit.

The first matching circuit may include an input matching circuit connected to the control terminal of the transistor.

In some embodiments, to tune the input impedance of the transistor die includes to increase the input impedance of the transistor die.

### BRIEF DESCRIPTION OF THE DRAWINGS

FIGS. 1A-1C are functional block diagrams of a conventional packaged transistor.

FIG. 2 is a schematic circuit diagram of a conventional packaged transistor;

FIGS. 3A-3C are functional diagrams of a packaged transistor die according to some embodiments of the present disclosure.

FIGS. 4A-4E are schematic circuit diagrams of transistor die according to some embodiments of the present disclosure.

FIGS. 5A-5C are schematic block diagrams of multi-amplifier circuits in which RF transistor amplifiers incorporating transistor dies according to embodiments may be used.

### DETAILED DESCRIPTION OF EMBODIMENTS

Embodiments of the inventive concepts will now be described in connection with the accompanying drawings. Some embodiments described herein provide a transistor die including a first partial matching circuit on the transistor die connected to at least one of a control terminal and a output terminal of the transistor, where the first partial matching circuit is configured to tune an input impedance of the transistor die. In some embodiments, the transistor die further includes the control terminal and the output terminal of the transistor coupled to a package including the transistor die, and the package includes a second partial matching circuit for the transistor die. In some embodiments, the second partial matching circuit for the transistor die is tunable for the transistor die to operate at a plurality of frequencies. In still further embodiments, the first partial matching circuit terminates a second harmonic frequency of a signal at a fundamental operating frequency of the transistor die.

It is also understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending of the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. The regions illustrated in the drawings are schematic in nature, and their shapes are not intended to illustrate the actual shape of a region of a device and are not intended to limit the scope of the disclosure unless explicitly stated otherwise. Further, lines that appear straight, horizontal, or vertical in the below drawings for schematic reasons will often be sloped, curved, non-horizontal, or non-vertical. Further, while the thicknesses of elements are meant to be schematic in nature.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

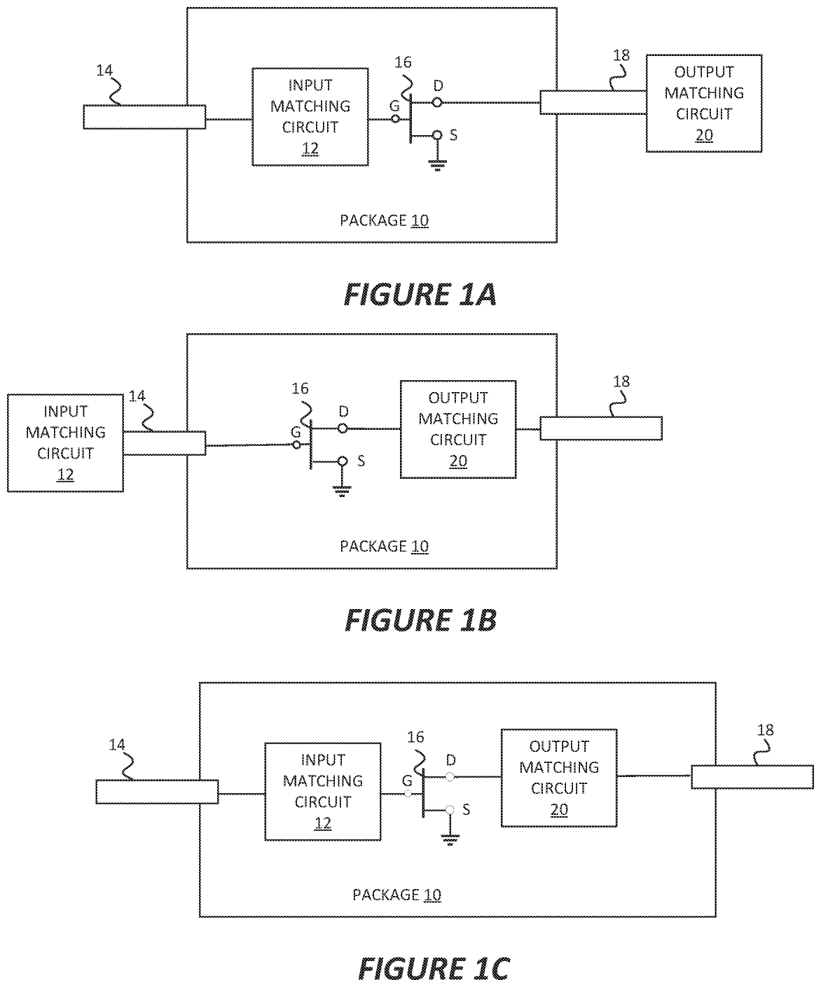

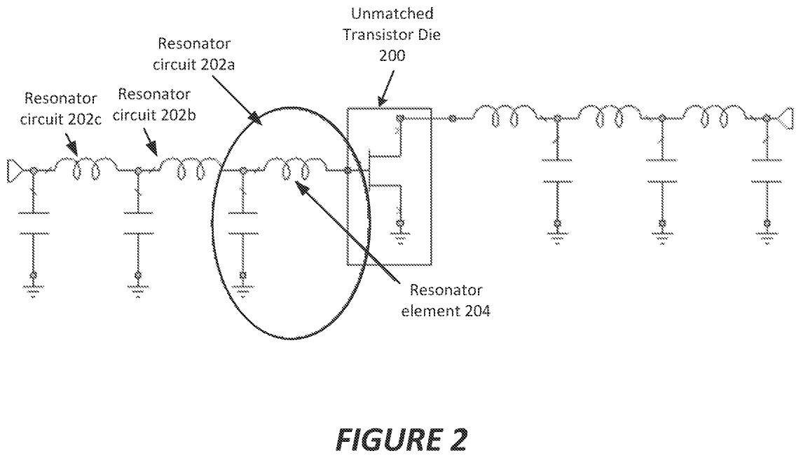

Matching circuits 12 and/or 20 have been provided within packaged transistors 10, as shown schematically in FIGS. 1A-1C. However, such packaged transistors typically do not include an integrated, internal matching circuit on a transistor die. Rather, such packaged transistors typically include a transistor die in the package along with matching components of an input matching circuit and/or an output matching circuit between the package leads and transistor die gate and drain pads. Depending on an impedance transformation ratio and bandwidth desired, the number of matching elements to match the transistor typically can be three resonator circuits (e.g., resonator circuits 202a, 202b, 202c as illustrated in FIG. 2). Each of the illustrated resonator circuits 202a, 202b, 202c includes a bond wire and a capacitor.

Referring to FIG. 2, as the frequency and/or power increases, the value of the resonator element 204 nearest the transistor die 200 can become impractical to implement due to, e.g., a size of the resonator element 204 for a desired performance level (e.g., a higher frequencies or increased power). For example, the resonator element 204 can be a bond wire that is coupled to a chip capacitor (as illustrated in FIG. 2) or a transmission line section. At higher frequencies (e.g., at one or more frequencies above 6 GHz and/or bandwidths of 2 GHZ or greater) and/or higher powers (e.g., 100 W or higher), input impedance of the transistor 16 can be unacceptably low when using a bond wire or a transmission line section as resonator element 204. To increase the impedance to an acceptable value, the size of the resonator element, such as a bond wire, can be too small. Furthermore, matching circuits 12 and/or 20 provided with packaged transistors typically are pre-tuned to a particular frequency or frequency range, and are not tunable after manufacture of the packaged transistor. Thus, as a consequence of inclusion of a matching circuit(s) in the package, the bandwidth and other performance (e.g., power levels) of the transistor can be limited.

With regard to various embodiments of the present disclosure, the terms “first partial matching circuit”, “second partial matching circuit”, “first matching circuit” and/or “second matching circuit” are used in a non-limiting manner and can refer to a matching circuit that is configured to tune an input impedance of the transistor die and/or for the transistor die to operate at a plurality of frequencies.

According to some embodiments of the present disclosure, a matching circuit can be provided on the transistor die that is configured to tune an input impedance of the transistor die. The matching circuit on the transistor die includes at least one resonator circuit on the transistor die. As a consequence, performance of a transistor die may be improved by adding more capability to the transistor, including increased input impedance, increased bandwidth, and/or increased power. Additionally, by integrating at least one resonator circuit on the transistor die and positioning another resonator circuit(s) off the transistor die (e.g., on a package that includes the transistor die), the transistor die can be designed to operate at different frequencies by using different components that are positioned off the transistor die. The different components can include an additional matching circuit(s) (e.g., two additional matching circuits) that are positioned off of and coupled to the transistor die. Thus, one or more of the respective matching circuits of the transistor die and package can be tuned to increase the input impedance of the transistor die and/or for the transistor die to operate at different frequencies. Further, based on inclusion of a matching circuit(s) on the transistor die, manufacturability of a package that includes the transistor die may be improved by eliminating wire bonds from the matching circuit(s) on the transistor die that can vary in performance throughout the manufacturing life of the transistor.

In some embodiments, a transistor die includes a transistor including a control terminal and an output terminal; and a first partial matching circuit connected to at least one of the control terminal of the transistor and the output terminal of the transistor. The first partial matching circuit is configured to tune an input impedance of the transistor die. The tuning can include to increase the input impedance of the transistor die.

Some embodiments of the transistor die further include the control terminal and the output terminal of the transistor coupled to a package including the transistor die. The package can include a second partial matching circuit for the transistor die. The second partial matching circuit for the transistor die can be tunable for the transistor die to operate at a plurality of frequencies.

The first partial matching circuit can include an input partial matching circuit connected to the control terminal of the transistor and/or an output partial matching circuit connected to the output terminal of the transistor. The first partial matching circuit can include a resonator circuit.

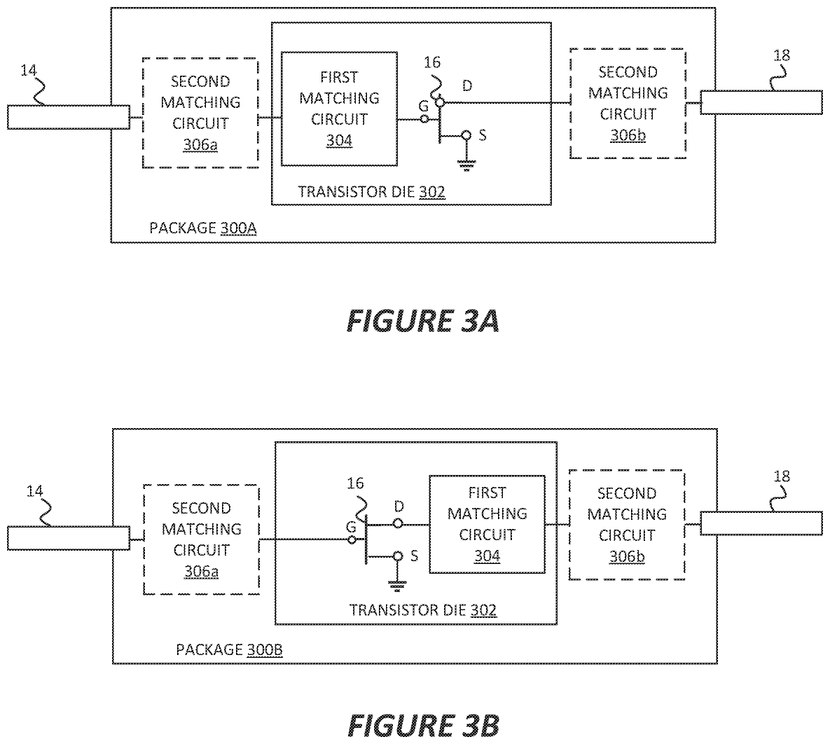

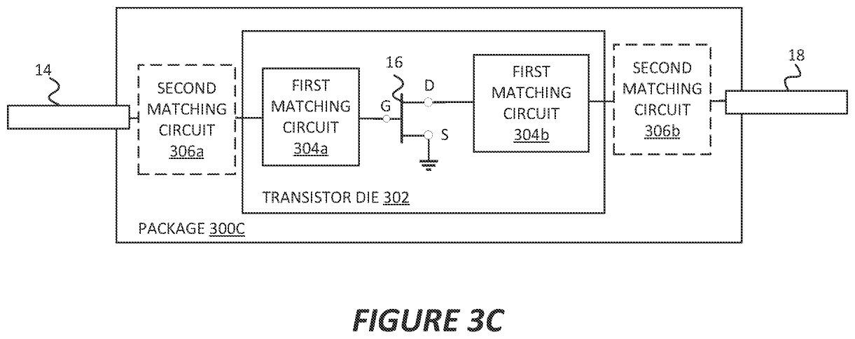

For example, as shown in FIG. 3A, a first matching circuit 304 can be included on a transistor die 302 at the input (control terminal/gate) of transistor 16. The first matching circuit 304 is a configured to tune an input impedance of the transistor die 302. As shown in FIG. 3A, package 300A includes transistor die 302 and, in some embodiments, can include one or more second matching circuits 306a, 306b that are connected to input lead 14 and/or output lead 18, respectively, of package 300A. In some embodiments, at least one of the second matching circuits 306a, 306b is tunable for the transistor die to operate at a plurality of frequencies (e.g., at one or more frequencies above 6 GHz). As discussed further herein, the first matching circuit 304 can be tuned to increase the input impedance of the transistor die 302.

In some embodiments, as shown in FIG. 3B, a first matching circuit 304 can be included on a transistor die 302 at the output terminal (drain D) of transistor 16. The first matching circuit 304 is configured to tune an output impedance of the transistor die 302. As shown in FIG. 3B, package 300B includes transistor die 302 and, in some embodiments, can include one or more second matching circuits 306a, 306b that are connected to input lead 14 and/or output lead 18, respectively, of package 300B. In some embodiments, at least one of the second matching circuits 306a, 306b is tunable is tunable for the transistor die to operate at a plurality of frequencies (e.g., at one or more frequencies above 6 GHz). As discussed further herein, the first matching circuit 304 can be tuned to increase the input impedance of the transistor die 302.

In some embodiments, as shown in FIG. 3C, a plurality of first matching circuits 304a, 304b can be included on a transistor die 302. The first matching circuits can include a first matching circuit 304a at the input (control terminal/gate) of transistor 16 and a first matching circuit 304b at the output terminal (drain D) of transistor 16. The first matching circuit 304a is configured to tune an input impedance of the transistor die 302. As shown in FIG. 3C, package 300C includes transistor die 302 and, in some embodiments, can include the first matching circuit 304b at the output terminal (drain D) of transistor 16, and one or more second matching circuits 306a, 306b that are connected to the input lead 14 and the output lead 18, respectively, of the package 300C. In some embodiments, at least one of the second matching circuits 306a, 306b are tunable for the transistor die to operate at a plurality of frequencies (e.g., at one or more frequencies above 6 GHz). As discussed further herein, the first matching circuit 304a can be tuned to increase the input impedance of the transistor die 302.

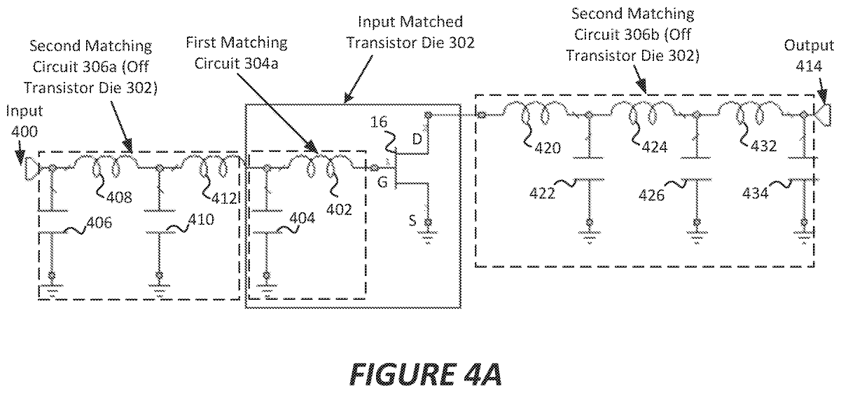

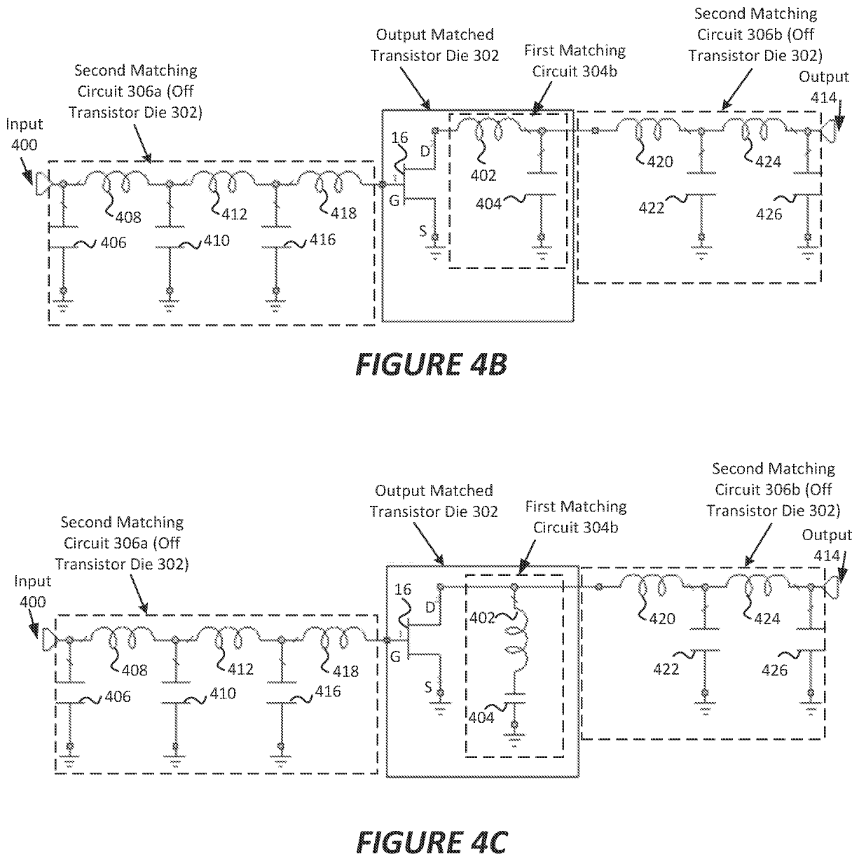

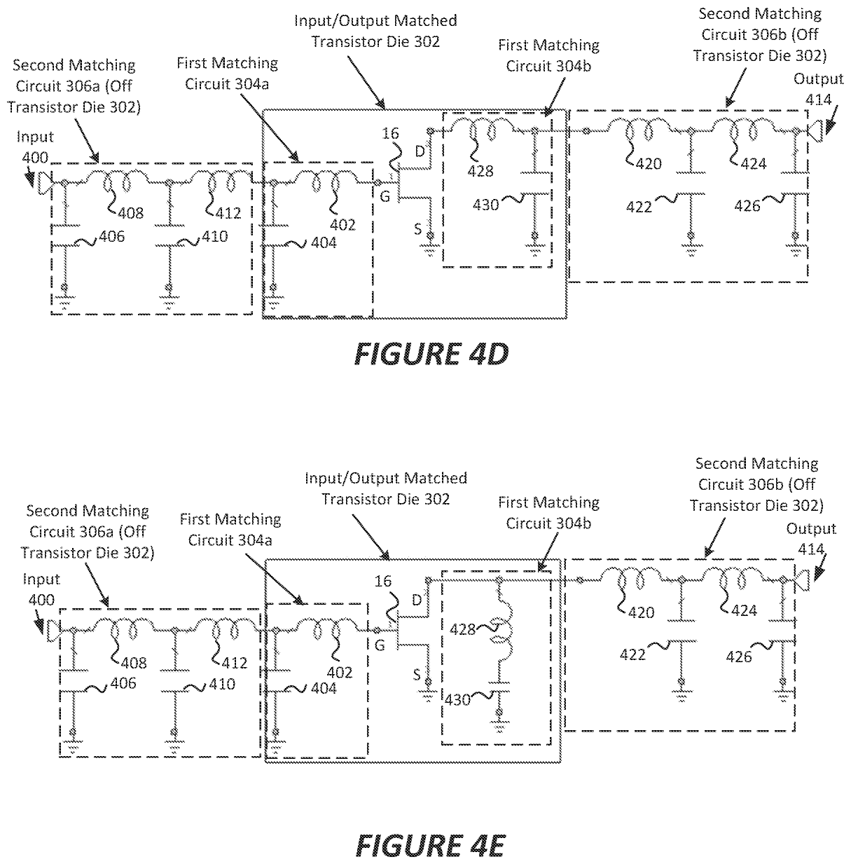

A schematic diagram for a package 300A as illustrated if FIG. 3A includes a transistor die 302 that includes a first matching circuit 304a according to embodiments of the present disclosure is illustrated in FIG. 4A. Referring to FIG. 4A, first matching circuit 304a is on transistor die 302 and is connected at the input (control terminal/gate G) of the transistor 16. The first matching circuit 304a may include a resonator element 402 (e.g., an inductor component) and a capacitor 404. The first matching circuit 304a of FIG. 4A is a resonator circuit that includes a series inductor element 402 with a shunt capacitor 406 connected to a ground terminal. The first matching circuit 304a may extend between the input (control terminal/gate of the transistor) of transistor 16 and a second matching circuit 306a that is in the package 300A off the transistor die 302. Second matching circuit 306a is at the input terminal (control terminal/gate) of the transistor die 302. Second matching circuit 306a can include two resonator circuits comprising resonator element 408 and capacitor 406, and resonator element 412 and capacitor 410, respectively.

As shown in FIG. 4A, the source S of the transistor 16 is grounded, and an output 414 of package 300 is connected to the drain D of the transistor 16 on transistor die 302. Optionally, as shown in FIG. 4A, a second matching circuit 306b is positioned in the package 300A off transistor die 302 and coupled to the output terminal (drain D) of transistor 16. As shown in FIG. 4A, second matching circuit 306b can include three resonator elements and three capacitors off the transistor die and extending between the transistor die 302 and the output 414.

It will be appreciated that the transistor die 302 includes a base on which the transistor 16 and a first matching circuit(s) are mounted/formed. The base of transistor die 302 can refer to any structural member on which transistor 16 and first matching circuit(s) are mounted/formed including, without limitation a die carrier, a substrate, a flange, or the like. Similarly, it will be appreciated that the packages 300A, 300B, 300C include a base on which the transistor die 302 and/or the second matching circuits 306a, 306b are mounted/formed. The base of package 300A, 300B, 300C can refer to any structural member on which the transistor die 302 and/or the second matching circuits 306a, 306b are mounted/formed including, without limitation a substrate, a flange, die carrier, or the like.

As shown in FIG. 4A, a matching network for the transistor includes the first matching circuit 304a on transistor die 302 and the second matching circuit 306a and/or 306b in package 300A. By integrating the first matching circuit 304a on transistor die 302, the inductance of the resonator element 402 and the capacitance of the capacitor 404 of the first matching circuit 304a may be selected so as to tune the input impedance of the transistor die 302 including, without limitation for example, for higher frequency/higher power devices. In some embodiments, the tuning increases the input impedance of the transistor die 302.

As further shown in FIG. 4A, when the transistor die 302 includes integrated first matching circuit 304a, the packaged transistor can be designed to operate at different frequencies by using different components that are off transistor die 302. For example, second matching circuit 306a and/or 306b can be positioned in the package 300A off transistor die 302 and is tunable for the transistor die to operate at a plurality of frequencies. The inductance of the inductor elements and the capacitance of the capacitors of the second matching circuit 306b of FIG. 4A may be selected so as to be tunable for the transistor die 302 to operate at a plurality of frequencies.

The output of transistor die 302 can be sensitive to second harmonic impedance. The first matching circuit 304a on transistor die 302 can terminate a second harmonic frequency of a signal at a fundamental operating frequency of the transistor die.

A schematic diagram for a package 300B as illustrated in FIG. 3B includes a transistor die 302 that includes a first matching circuit 304b according to embodiments of the present disclosure is illustrated in FIG. 4B. Referring to FIG. 4B, first matching circuit 304b is on transistor die 302 and is connected at the output terminal (drain D) of the transistor 16. The first matching circuit 304b may include a resonator element 402 (e.g., an inductor component) and a capacitor 404. The first matching circuit 304b of FIG. 4B is a resonator circuit that includes a series inductor element 402 with a shunt capacitor 406 connected to a ground terminal. The first matching circuit 304b may extend between the output terminal (drain D) of the transistor 16 and a second matching circuit 306b that is in package 300B off the transistor die 302. Second matching circuit 306b is at the output terminal (drain D) of the transistor die 302. Second matching circuit 306b can include two resonator circuits comprising resonator element 420 and capacitor 422, and resonator element 424 and capacitor 426, respectively.

As shown in FIG. 4B, the source S of the transistor 16 is grounded, and an output 414 of package 300B is connected to the drain D of the transistor 16 on transistor die 302 via the second matching circuit 306b. Optionally, as shown in FIG. 4B, a second matching circuit 306a is positioned in package 300B off transistor die 302 and coupled to the input terminal (control terminal/gate G) of transistor 16. As shown in FIG. 4B, second matching circuit 306a can include three resonator elements 408, 412, 418 and three capacitors 406, 410, 416.

As shown in FIG. 4B, a matching network for the transistor includes the first matching circuit 304b on transistor die 302 and the second matching circuit 306a and/or 306b in package 300B. By integrating the first matching circuit 304b on transistor die 302, the inductance of the resonator element 402 and the capacitance of the capacitor 404 of the first matching circuit 304b may be selected so as to tune the input impedance of the transistor die 302 including, without limitation for example, for higher frequency/higher power devices. In some embodiments, the tuning increases the input impedance of the transistor die 302.

As further shown in FIG. 4B, when the transistor die 302 includes integrated first matching circuit 304b, the packaged transistor can be designed to operate at different frequencies by using different components that are off transistor die 302. For example, second matching circuit 306b can be positioned in package 300B off transistor die 302 and is tunable for the transistor die to operate at a plurality of frequencies. The inductance of the inductor elements and the capacitance of the capacitors of the second matching circuit 306b of FIG. 4B may be selected so as to be tunable for the transistor die 302 to operate at a plurality of frequencies.

The output of transistor die 302 can be sensitive to second harmonic impedance. The first matching circuit 304b on transistor die 302 can terminate a second harmonic frequency of a signal at a fundamental operating frequency of the transistor die.

Another schematic diagram for a package 300B as illustrated in FIG. 3B includes a transistor die 302 that includes a first matching circuit 304b according to embodiments of the present disclosure is illustrated in FIG. 4C. As shown in FIG. 4C, in other embodiments, the first matching circuit 304b is on transistor die 302 and the second matching circuits 306a, 306b in package 300B are in the same positions illustrated in FIG. 4B. For ease of discussion, differences are described compared to the schematic diagram of FIG. 4B. Thus, components and operations that may be substantially similar to those described with respect to FIG. 4B are not repeated, such that the descriptions thereof are generally applicable to the corresponding components/operations of FIG. 4C. In embodiments illustrated in FIG. 4C, while the first matching circuit 304b also includes an inductor component 402 and a capacitor component 406, in the embodiments illustrated in FIG. 4C, the first matching circuit 304b is a series resonator circuit that includes the inductor element 402 and a shunt capacitor 406 connected in series to a ground terminal.

As shown in FIG. 4C, a matching network for the transistor includes the first matching circuit 304 on transistor die 302 and the second matching circuit 306b in package 300B. By integrating the first matching circuit 304b on transistor die 302, the inductance of the resonator element 402 and the capacitance of the capacitor 404 of the first matching circuit 304 may be selected so as to tune the input impedance of the transistor die 302 including, without limitation for example, for higher frequency/higher power devices. In some embodiments, the tuning increases the input impedance of the transistor die 302.

As further shown in FIG. 4C, when the transistor die 302 includes integrated first matching circuit 304b, the packaged transistor can be designed to operate at different frequencies by using different components that are off transistor die 302. For example, second matching circuit 306b can be positioned in the package 300B off transistor die 302 and is tunable for the transistor die to operate at a plurality of frequencies. The inductance of the inductor elements and the capacitance of the capacitors of the second matching circuit 306b of FIG. 4C may be selected so as to be tunable for the transistor die 302 to operate at a plurality of frequencies.

The output of transistor die 302 can be sensitive to second harmonic impedance. The first matching circuit 304b on transistor die 302 can terminate a second harmonic frequency of a signal at a fundamental operating frequency of the transistor die.

A schematic diagram for a package 300C as illustrated of FIG. 3C includes a transistor die 302 that includes two first matching circuits 304a and 304b according to embodiments of the present disclosure is illustrated in FIG. 4D. Referring to FIG. 4D, a first matching circuit 304a is on transistor die 302 and is connected at the input (control terminal/gate) of the transistor 16. The first matching circuit 304a may include a resonator element 402 (e.g., an inductor component) and a capacitor 404. The first matching circuit 304a of FIG. 4D is a resonator circuit that includes a series inductor element 402 with a shunt capacitor 406 connected to a ground terminal. The first matching circuit 304 may extend between the input (control terminal/gate of the transistor) of transistor 16 and a second matching circuit 306a that is in package 300C off the transistor die 302. Second matching circuit 306a is at the input terminal (control terminal/gate) of the transistor die 302. Second matching circuit 306a can include two resonator circuits comprising resonator element 408 and capacitor 406, and resonator element 412 and capacitor 410, respectively.

Referring to FIG. 4D, transistor die 302 also includes first matching circuit 304b. First matching circuit 304b is connected at the output terminal (drain D) of the transistor 16. The first matching circuit 304b may include a resonator element 428 (e.g., an inductor component) and a capacitor 430. The first matching circuit 304b of FIG. 4D is a resonator circuit that includes a series inductor element 428 with a shunt capacitor 430 connected to a ground terminal. The first matching circuit 304b may extend between the output terminal (drain D) of the transistor 16 and a second matching circuit 306b that is off the transistor die 302. Second matching circuit 306b is at the output terminal (drain D) of the transistor die 302. Second matching circuit 306b can include two resonator circuits comprising resonator element 420 and capacitor 422, and resonator element 424 and capacitor 426, respectively.

As shown in FIG. 4D, a matching network for the transistor includes the first matching circuits 304a, 304b on transistor die 302 and the second matching circuits 306a, 306b in package 300C. By integrating the first matching circuits 304a, 304b on transistor die 302, the inductance of the resonator elements 402, 428 and the capacitance of the capacitors 404, 430 of the first matching circuits 304a, 304b may be selected so as to tune the input impedance of the transistor die 302 including, without limitation for example, for higher frequency/higher power devices. In some embodiments, the tuning increases the input impedance of the transistor die 302.

As further shown in FIG. 4D, when the transistor die 302 includes integrated first matching circuits 304a, 304b, the packaged transistor can be designed to operate at different frequencies by using different components that are off transistor die 302. For example, second matching circuits 306a and/or 306b can be positioned in package 300C off transistor die 302 and are tunable for the transistor die to operate at a plurality of frequencies. The inductance of the inductor elements and the capacitance of the capacitors of the second matching circuits 306a and/or 306b of FIG. 4D may be selected so as to be tunable for the transistor die 302 to operate at a plurality of frequencies.

The output of transistor die 302 can be sensitive to second harmonic impedance. The first matching circuits 304a and/or 304b on transistor die 302 can terminate a second harmonic frequency of a signal at a fundamental operating frequency of the transistor die.

Another schematic diagram for a package 300C as illustrated in FIG. 3C includes a transistor die 302 that includes two first matching circuits 304a, 304b according to other embodiments of the present disclosure is illustrated in FIG. 4E. As shown in FIG. 4E, first matching circuits 304a, 304b are on transistor die 302 and second matching circuits 306a, 306b are in package 300C in the same positions illustrated in FIG. 4D. For ease of discussion, differences are described compared to the schematic diagram of FIG. 4D. Thus, components and operations that may be substantially similar to those described with respect to FIG. 4D are not repeated, such that the descriptions thereof are generally applicable to the corresponding components/operations of FIG. 4E. In embodiments illustrated in FIG. 4E, while the first matching circuit 304b also includes an inductor component 428 and a capacitor 430, in the embodiments illustrated in FIG. 4E, the first matching circuit 304b is a series resonator circuit that includes the inductor element 428 and a shunt capacitor 430 connected in series to a ground terminal.

As shown in FIG. 4E, a matching network for the transistor includes the first matching circuits 304a, 304b on transistor die 302 and the second matching circuits 306a, 306b in package 300C. By integrating the first matching circuits 304a, 304b on transistor die 302, the inductance of the resonator elements 402, 428 and the capacitance of the capacitors 404, 430 of the first matching circuits 304a, 304b may be selected so as to tune the input impedance of the transistor die 302 including, without limitation for example, for higher frequency/higher power devices. In some embodiments, the tuning increases the input impedance of the transistor die 302.

As further shown in FIG. 4E, when the transistor die 302 includes integrated first matching circuits 304a, 304b, the packaged transistor can be designed to operate at different frequencies by using different components that are off transistor die 302. For example, second matching circuits 306a and/or 306b can be positioned in package 300C off transistor die 302 and are tunable for the transistor die to operate at a plurality of frequencies. The inductance of the inductor elements and the capacitance of the capacitors of the second matching circuits 306a and/or 306b of FIG. 4E may be selected so as to be tunable for the transistor die 302 to operate at a plurality of frequencies.

The output of transistor die 302 can be sensitive to second harmonic impedance. The first matching circuits 304a and/or 304b on transistor die 302 can terminate a second harmonic frequency of a signal at a fundamental operating frequency of the transistor die.

Thus, in some embodiments, the first partial matching circuit includes a resonator circuit. The resonator circuit of the transistor die can include a series resonant circuit including an inductive element and a shunt capacitor connected in series to a ground terminal; a shunt inductive element; and/or a series capacitor. The resonator circuit can be selected to increase an input impedance of the transistor die.

In some embodiments, the first partial matching circuit terminates a second harmonic frequency of a signal at a fundamental operating frequency of the transistor die.

In other embodiments, a power transistor die is provided. The power transistor die includes a transistor including a control terminal and an output terminal and is configured to operate a fundamental operating frequency. The power transistor die further includes a first matching circuit connected to at least one of the control terminal of the transistor and the output terminal of the transistor. The first matching circuit is configured to tune an input impedance of the transistor die for signals at a harmonic frequency of the fundamental operating frequency. The power transistor die further includes the control terminal and the output terminal of the transistor coupled to a package that includes the transistor die. The package includes a second matching circuit for the transistor die that is tunable for the transistor die to operate at a plurality of frequencies.

The tuning of the first matching circuit can be configured to increase the input impedance of the transistor die.

The first matching circuit of the power transistor die can include an input matching circuit connected to the control terminal of the transistor and/or an output matching circuit connected to the output terminal of the transistor. The first matching circuit can include a resonator circuit. The resonator circuit of the power transistor die can include a series resonant circuit including an inductive element and a shunt capacitor connected in series to a ground terminal; a shunt inductive element; and/or a series capacitor. The resonator circuit can be selected to increase an input impedance of the power transistor die.

Transistor dies as described herein may be used in amplifiers that operate in a wide variety of different frequency bands. In some embodiments, RF transistor amplifiers incorporating transistor dies as described herein may be configured to operate at frequencies greater than 1 GHz. In other embodiments, the RF transistor amplifiers may be configured to operate at frequencies greater than 2.5 GHz. In still other embodiments, the RF transistor amplifiers may be configured to operate at frequencies greater than 3.1 GHz. In yet additional embodiments, the RF transistor amplifiers may be configured to operate at frequencies greater than 5 GHz. In some embodiments, the RF transistor amplifiers may be configured to operate in at least one of the 2.5-2.7 GHz, 3.4-4.2 GHz, 5.1-5.8 GHz, 12-18 GHz, 18-27 GHz, 27-40 GHz or 40-75 GHz frequency bands or sub-portions thereof.

Although embodiments of the inventive concepts have been discussed above with respect to HEMT devices, it will be understood that the inventive concepts described herein may be applied to other types of semiconductor devices, such as MOSFETs, DMOS transistors, and/or laterally diffused MOS (LDMOS) transistors.

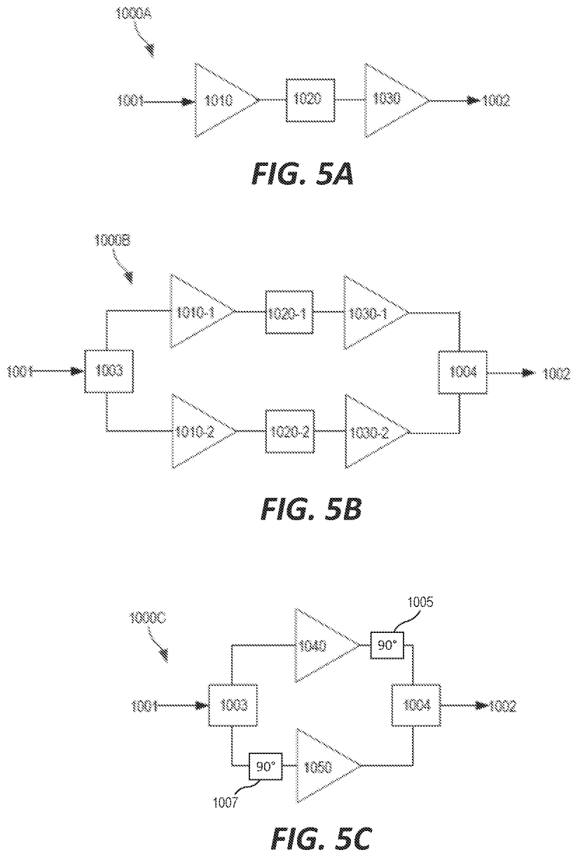

RF transistor amplifiers incorporating transistor dies described herein can be used in standalone RF transistor amplifiers and/or in multiple RF transistor amplifiers. Examples of how the RF transistor amplifiers according to some embodiments may be used in applications that include multiple amplifiers will be discussed with reference to FIGS. 5A-5C.

Referring to FIG. 5A, an RF transistor amplifier 1000A is schematically illustrated that includes a pre-amplifier 1010 and a main amplifier 1030 that are electrically connected in series. As shown in FIG. 5A, RF transistor amplifier 1000A includes an RF input 1001, the pre-amplifier 1010, an inter-stage impedance matching network 1020, the main amplifier 1030, and an RF output 1002. The inter-stage impedance matching network 1020 may include, for example, inductors and/or capacitors arranged in any appropriate configuration of first and/or second matching circuits discussed herein in order to form a circuit that improves the impedance match between the output of pre-amplifier 1010 and the input of main amplifier 1030. While not shown in FIG. 5A, RF transistor amplifier 1000A may further include an input first and/or second matching circuit that is interposed between RF input 1001 and pre-amplifier 1010, and/or an output first and/or second matching circuit that is interposed between the main amplifier 1030 and the RF output 1002. The RF transistor amplifiers according to embodiments may be used to implement either or both of the pre-amplifier 1010 and the main amplifier 1030.

Referring to FIG. 5B, an RF transistor amplifier 1000B is schematically illustrated that includes an RF input 1001, a pair of pre-amplifiers 1010-1, 1010-2, a pair of inter-stage impedance matching networks 1020-1, 1020-2, a pair of main amplifiers 1030-1, 1030-2, and an RF output 1002. A splitter 1003 and a combiner 1004 are also provided. Pre-amplifier 1010-1 and main amplifier 1030-1 (which are electrically connected in series) are arranged electrically in parallel with pre-amplifier 1010-2 and main amplifier 1030-2 (which are electrically connected in series). As with the RF transistor amplifier 1000A of FIG. 8A, RF transistor amplifier 1000B may further include an input first and/or second matching circuit that is interposed between RF input 1001 and pre-amplifiers 1010-1, 1010-2, and/or an output first and/or second matching circuit that is interposed between the main amplifiers 1030-1, 1030-2 and the RF output 1002.

As shown in FIG. 5C, the RF transistor amplifiers according to some embodiments may also be used to implement Doherty amplifiers. As is known in the art, a Doherty amplifier circuit includes first and second (or more) power-combined amplifiers. The first amplifier is referred to as the “main” or “carrier” amplifier and the second amplifier is referred to as the “peaking” amplifier. The two amplifiers may be biased differently. For example, the main amplifier may comprise a Class AB or a Class B amplifier while the peaking amplifier may be a Class C amplifier in one common Doherty amplifier implementation. The Doherty amplifier may operate more efficiently than balanced amplifiers when operating at power levels that are backed off from saturation. An RF signal input to a Doherty amplifier is split (e.g., using a quadrature coupler), and the outputs of the two amplifiers are combined. The main amplifier is configured to turn on first (i.e., at lower input power levels) and hence only the main amplifier will operate at lower power levels. As the input power level is increased towards saturation, the peaking amplifier turns on and the input RF signal is split between the main and peaking amplifiers.

As shown in FIG. 5C, the Doherty RF transistor amplifier 1000C includes an RF input 1001, an input splitter 1003, a main amplifier 1040, a peaking amplifier 1050, an output combiner 1004 and an RF output 1002. The Doherty RF transistor amplifier 1000C includes a 90° transformer 1007 at the input of the peaking amplifier 1050 and a 90° transformer 1005 at the input of the main amplifier 1040, and may optionally include input first and/or second matching circuits and/or an output first and/or second matching circuit as discussed herein. The main amplifier 1040 and/or the peaking amplifier 1050 may be implemented using any of the above-described RF transistor amplifiers according to embodiments.

The RF transistor amplifiers according to embodiments may be formed as discrete devices, or may be formed as a transistor die coupled to a Monolithic Microwave Integrated Circuit (MMIC). A MMIC refers to an integrated circuit that operates on radio and/or microwave frequency signals in which all of the circuitry for a particular function is integrated into a single semiconductor chip. An example MMIC device in accordance with some embodiments is coupled to a transistor die as discussed herein, where the transistor die includes at least one first matching circuit on the transistor die and the MIMIC includes at least one second matching circuit. The transistor die includes the associated first matching circuit(s), feed networks and the like that are all implemented on a common substrate; and the MIMIC includes the associated second matching circuit(s), feed networks and the like that are implemented on another common substrate that is separate from the substrate of the transistor die.

Many variations of the features of the above embodiments are possible. Transistor structures with features that may be used in embodiments of the present invention are disclosed in the following commonly assigned publications, the contents of each of which are fully incorporated by reference herein in their entirety: U.S. Pat. No. 6,849,882 to Chavarkar et al. and entitled “Group-III Nitride Based High Electron Mobility Transistor (HEMT) With Barrier/Spacer Layer”; U.S. Pat. No. 7,230,284 to Parikh et al. and entitled “Insulating Gate AlGaN/GaN HEMT”; U.S. Pat. No. 7,501,669 to Parikh et al. and entitled “Wide Bandgap Transistor Devices With Field Plates”; U.S. Pat. No. 7,126,426 to Mishra et al. and entitled “Cascode Amplifier Structures Including Wide Bandgap Field Effect Transistor With Field Plates”; U.S. Pat. No. 7,550,783 to Wu et al. and entitled “Wide Bandgap HEMTs With Source Connected Field Plates”; U.S. Pat. No. 7,573,078 to Wu et al. and entitled “Wide Bandgap Transistors With Multiple Field Plates”; U.S. Pat. Pub. No. 2005/0253167 to Wu et al. and entitled “Wide Bandgap Field Effect Transistors With Source Connected Field Plates”; U.S. Pat. Pub. No. 2006/0202272 to Wu et al. and entitled “Wide Bandgap Transistors With Gate-Source Field Plates”; U.S. Pat. Pub. No. 2008/0128752 to Wu and entitled “GaN Based HEMTs With Buried Field Plates”; U.S. Pat. Pub. No. 2010/0276698 to Moore et al. and entitled “Gate Electrodes For Millimeter-Wave Operation and Methods of Fabrication; U.S. Pat. Pub. No. 2012/0049973 to Smith, Jr. et al. and entitled “High Power Gallium Nitride Field Effect Transistor Switches”; U.S. Pat. Pub. No. 2012/0194276 to Fisher and entitled “Low Noise Amplifiers Including Group III Nitride Based High Electron Mobility Transistors”; and U.S. Pat. No. 9,847,411 to Sriram et al. entitled “Recessed field plate transistor structures.”

Although embodiments of the inventive concepts have been described in considerable detail with reference to certain configurations thereof, other versions are possible. The field plates and gates can also have many different shapes and can be connected to the source contact in many different ways. Accordingly, the spirit and scope of the invention should not be limited to the specific embodiments described above.

What is claimed is:

1. A transistor die, comprising:
a transistor including a control terminal and an output terminal; and
a first partial matching circuit connected to at least one of the control terminal of the transistor and the output terminal of the transistor, the first partial matching circuit configured to tune an input impedance of the transistor die.

2. The transistor die of claim 1, further comprising:
the control terminal and the output terminal of the transistor coupled to a package comprising the transistor die, the package including a second partial matching circuit for the transistor die.

3. The transistor die of claim 2, wherein the second partial matching circuit for the transistor die is tunable for the transistor die to operate at a plurality of frequencies.

4. The transistor die of claim 1, wherein to tune the input impedance of the transistor die comprises to increase the input impedance of the transistor die.

5. The transistor die of claim 1, wherein the first partial matching circuit comprises an input partial matching circuit connected to the control terminal of the transistor.

6. The transistor die of claim 1, wherein the first partial matching circuit comprises an output partial matching circuit connected to the output terminal of the transistor.

7. The transistor die of claim 1, wherein the first partial matching circuit comprises an input partial matching circuit connected to the control terminal of the transistor and/or an output partial matching circuit connected to the output terminal of the transistor.

8. The transistor die of claim 1, wherein the first partial matching circuit comprises a resonator circuit.

9. The transistor die of claim 8, wherein the resonator circuit comprises a series resonator circuit including an inductive element and a shunt capacitor connected in series to a ground terminal.

10. The transistor die of claim 8, wherein the resonator circuit includes a shunt inductive element.

11. The transistor die of claim 8, wherein the resonator circuit includes a series capacitor.

12. The transistor of claim 8, wherein the resonator circuit is selected to increase an input impedance of the transistor die.

13. The transistor die of claim 1, wherein the first partial matching circuit terminates a second harmonic frequency of a signal at a fundamental operating frequency of the transistor die.

14. A power transistor die, comprising:
a transistor including a control terminal and an output terminal and is configured to operate a fundamental operating frequency; and
a first matching circuit connected to at least one of the control terminal of the transistor and the output terminal of the transistor, the first matching circuit configured to tune an input impedance of the transistor die for signals at a harmonic frequency of the fundamental operating frequency; and
the control terminal and the output terminal of the transistor coupled to a package comprising the transistor die, the package including a second matching circuit for the transistor die that is tunable for the transistor die to operate at a plurality of frequencies.

15. The power transistor die of claim 14, wherein the first matching circuit comprises an input matching circuit connected to the control terminal of the transistor.

16. The power transistor die of claim 14, wherein to tune the input impedance of the transistor die comprises to increase the input impedance of the transistor die.

17. The power transistor die of claim 14, wherein the first matching circuit comprises an output matching circuit connected to the output terminal of the transistor.

18. The power transistor die of claim 14, wherein the first matching circuit comprises an input matching circuit connected to the control terminal of the transistor and/or an output matching circuit connected to the output terminal of the transistor.

19. The power transistor die of claim 14, wherein the first matching circuit comprises a resonator circuit.

20. The power transistor die of claim 19, wherein the resonator circuit comprises a series resonator circuit including an inductive element and a shunt capacitor connected in series to a ground terminal.

21. The power transistor die of claim 19, wherein the resonator circuit includes a shunt inductive element.

22. The power transistor die of claim 19, wherein the resonator circuit includes a series capacitor.

23. The power transistor of claim 19, wherein the resonator circuit is selected to increase an input impedance of the power transistor die.

24. A packaged device, comprising:
a transistor die comprising a transistor including a control terminal and an output terminal,
a first partial matching circuit connected to at least one of the control terminal of the transistor and the output terminal of the transistor, the first partial matching circuit configured to tune an input impedance of the transistor die; and
a package that houses the transistor die and the first partial matching circuit.

25. The package device of claim 24, wherein the control terminal and the output terminal of the transistor are coupled to the package including the transistor die, and the package further includes a second partial matching circuit for the transistor die.

26. The package device of claim 25, wherein the second partial matching circuit for the transistor die is tunable for the transistor die to operate at a plurality of frequencies.

27. The package device of claim 24, wherein to tune the input impedance of the transistor die comprises to increase the input impedance of the transistor die.

28. A packaged device, comprising;
a power transistor die including a transistor, the transistor including a control terminal and an output terminal and is configured to operate a fundamental operating frequency,
a first matching circuit connected to at least one of the control terminal of the transistor and the output terminal of the transistor, the first matching circuit configured to tune an input impedance of the transistor die for signals at a harmonic frequency of the fundamental operating frequency,
the control terminal and the output terminal of the transistor are coupled to a package including the transistor die, the package including a second matching circuit for the transistor die that is tunable for the transistor die to operate at a plurality of frequencies; and
a package that houses the power transistor die, the first matching circuit, and the second matching circuit.

29. The package device of claim 28, wherein the first matching circuit comprises an input matching circuit connected to the control terminal of the transistor.

30. The package device of claim 28, wherein to tune the input impedance of the transistor die comprises to increase the input impedance of the transistor die.
